(19) United States
(12) Patent Application Publication
(10) Pub. No.: US 2012/0187983 A1
(43) Pub. Date: Jul. 26, 2012

(54) FREQUENCY GENERATOR

(75) Inventors: Chung-Hsien LIN, Hsinchu (TW); Jui-Cheng HUANG, Hsinchu City (TW); Wan-Te CHEN, Danshui Township (TW); Chia-Hua CHU, Zhubei City (TW)

(73) Assignee: TAIWAN SEMICONDUCTOR MANUFACTURING COMPANY, LTD., Hsinchu (TW)

(21) Appl. No.: 13/009,952

(22) Filed: Jan. 20, 2011

(51) Int. Cl. H03B 19/00

(52) U.S. Cl. 327/113

(57) ABSTRACT

A mechanical frequency generator has a first mechanical resonator and a second mechanical resonator and a circuit connected with the first and second mechanical resonators. The first and second mechanical resonators having substantially the same resonator frequency coefficients as a function of an environment of the first and the second mechanical resonators. The first mechanical resonator differing in size from the second mechanical resonator. The circuit adapted to generate a difference frequency signal responsive to the first and second mechanical resonator frequency signals and based on the first and the second predetermined resonant frequencies.

### BACKGROUND

The present disclosure relates to frequency generators for use as clock circuits and frequency references in electronic devices.

Mechanical resonators are the basis of many frequency references used in timepieces, computers and control systems. Such mechanical resonators include pendulums, balance wheels, tuning forks and quartz crystals. Mechanical resonators are affected by temperature changes with the resonant frequency increasing or decreasing in response to temperature fluctuations. In well-designed mechanical resonators, the changes in frequency with changes in temperature are minimized, however, it is difficult to completely remove the changes due to temperature. The change of resonant frequency with the change in temperature is known as the temperature coefficient of the resonator. A resonator also has coefficients for the change in frequency due to other variables in the environment. Thus, a resonator will have coefficients, for example, for humidity, acceleration, gravity, radiation, light or age.

Accurate and stable reference frequencies are useful in the development of modern computers and communications equipment. Usually, quartz crystal resonators are used to generate reference frequencies because such resonators are very stable with temperature fluctuations and do not experience significant time drift. Quartz crystal resonators are large compared with other components used in modern computers and communications equipment. The quartz crystals must be hermetically sealed and are too large to be integrated onto the surface of a silicon chip or to be easily packaged next to a silicon die in a package.

In recent years, micro electromechanical systems (MEMS) have been developed that include micromechanical resonators. Micromechanical resonators can be very small in comparison with quartz crystal based resonators and are often integrated into silicon chips that also contain electronic circuits for driving the micromechanical resonator. Due to the materials used to form the micromechanical resonators and the constraints in layout and design of the micromechanical resonators, temperature coefficients with regard to frequency are poor compared with quartz crystal resonators. For this reason, micromechanical resonators have not replaced quartz crystal resonators in most applications.

### DESCRIPTION OF THE DRAWINGS

One or more embodiments are illustrated by way of example, and not by limitation, in the figures of the accompanying drawings, wherein elements having the same reference numeral designations represent like elements throughout and wherein:

FIG. 1 is a high-level functional diagram of a frequency generator according to an embodiment:

FIG. 2 is a top view of a mechanical resonator according to an embodiment;

FIG. 3 is a diagram of the oscillation mode of the suspended plate in FIG. 2;

FIG. 4 is a cross-section through FIG. 2 along the line A-A′;

FIG. 5 is a top view of mechanical resonators usable in the FIG. 1 embodiment;

FIG. 6 is a plot of frequency versus temperature for two mechanical resonators for the embodiment in FIGS. 1, 2 and 5;

FIG. 7 is a schematic diagram of a mixer circuit according to an embodiment;

FIG. 8 is a schematic diagram of a filter circuit according to an embodiment; and

FIG. 9 is a flow diagram of a method of producing a reference frequency using mechanical resonators according to an embodiment.

### DETAILED DESCRIPTION

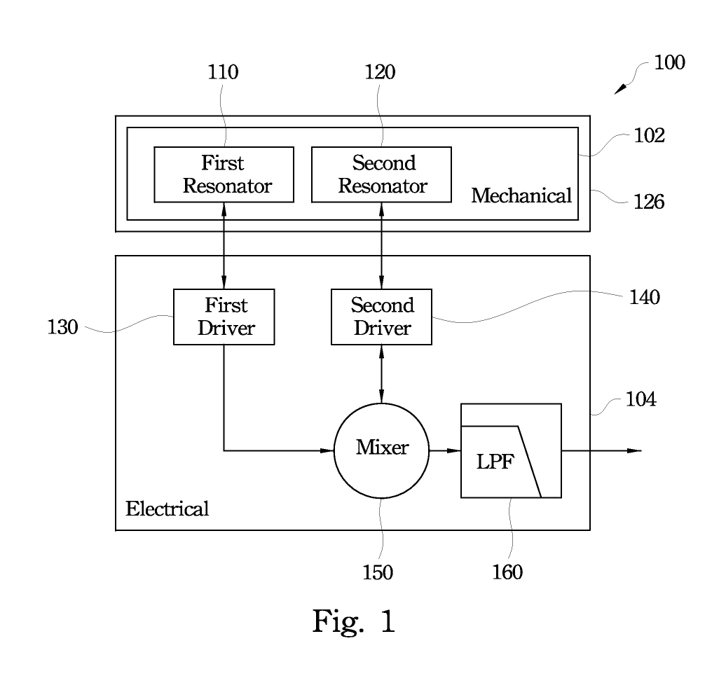

FIG. 1 is a high-level schematic diagram of a frequency generator 100 according to an embodiment. The frequency generator 100 may be used in place of a quartz crystal resonator in many applications. The frequency generator 100 comprises a mechanical portion 102 connected with an electrical portion 104. In some embodiments, the mechanical portion 102 and the electrical portion 104 are formed on the same substrate. In other embodiments, the mechanical portion 102 and electrical portion 104 are formed on separate substrates. In embodiments in which the mechanical portion 102 and electrical portion 104 are formed on separate substrates, electrical connections between the two substrates are formed by, for example, wire bonding or die bonding.

Mechanical portion 102 comprises a first mechanical resonator 110 and a second mechanical resonator 120. Each of the first and second mechanical resonators 110, 120 have a predetermined resonant frequency. The predetermined resonant frequency of the first mechanical resonator 110 differs from the predetermined resonant frequency of the second mechanical resonator 120.

An optional seal 126 seals the mechanical part 102 from the environment. In some embodiments, seal 126 is a hermetic seal.

The electrical portion 104 comprises first and second drivers 130, 140 coupled with a mixer circuit 150 which, in turn, is coupled with a filter circuit 160. The first and second drivers 130, 140 are coupled with the first and second mechanical resonators 110, 120, respectively.

The first driver 130 is arranged to drive the first mechanical resonator 110 and cause the first mechanical resonator to oscillate at the resonant frequency of the first mechanical resonator. The second driver 140 is arranged to drive the second mechanical resonator 120 and cause the second mechanical resonator to oscillate at the resonant frequency of the second mechanical resonator. Responsive to being driven by the first and second drivers 130, 140, the first and second mechanical resonators 110, 120 generate resonator output signals having a frequency corresponding to the resonant frequency of each of the mechanical resonators 110, 120 which are transmitted to the first and second drivers. The first and second drivers 130, 140 output reference signals having frequencies corresponding to the resonant frequencies of the respective first and second mechanical resonators 110, 120.

The implementation of the first and second drivers 130, 140 depends upon the specific mechanical resonator used to form mechanical resonators 110, 120. The driver receives sense signals from the mechanical resonator indicating at least one of a position, velocity or acceleration of a part of the mechanical resonator. Based on the received sense signals, the first and second drivers 130, 140 output a drive signal to the mechanical resonators 110, 120 that is timed and has an amplitude to keep the resonators 110, 120 resonating with a constant amplitude.

The first and second drivers 130, 140 comprise, for example, one or more of an amplifier, a transconductance amplifier, a transimpedance amplifier, an integrator, a differentiator circuit or a filter circuit depending upon the specific mechanical resonator used to form mechanical resonators 110, 120.

In some embodiments, the first and second drivers 130, 140 output as the reference signals the sense signals received from the mechanical resonators 110, 120. In other embodiments, the first and second drivers 130, 140 output as the reference signals the drive signals output to the mechanical resonators 110, 120.

Mixer circuit 150 is connected with the first and second drivers 130, 140 and receives the reference signals from the first and second drivers 130, 140. The mixer circuit 150 combines the first and second signals using a non-linear process so that a mixed output signal from the mixer circuit contains frequencies in addition to the frequencies of the first and the second mechanical resonators 110, 120. In at least some embodiments, the additional frequencies include the sum and difference frequencies of the first and second mechanical resonators 110, 120 as well as harmonic frequencies of the first and second mechanical resonators and various other products of the first and second mechanical resonator frequencies.

Filter circuit 160 is connected with the mixer circuit 150 and receives the mixed output signal from the mixer circuit. The mixed output signal from the mixer circuit 150 is filtered by the filter circuit 160. The filter circuit 160 transmits the difference frequency between the signals from the first and second mechanical resonators 110, 120 to a filtered output of the filter circuit. In at least some embodiments, filter circuit 160 filters the output from mixer circuit 150 in order to selectively transmit the difference frequency between the first and second mechanical resonators.

The first and second mechanical resonators 110, 120 are configured to have substantially the same temperature coefficients with respect to frequency. Further, the resonant frequencies of the first and second mechanical resonators 110, 120 are selected such that the difference frequency between signals from the first and second mechanical resonators is the desired frequency output for the frequency generator 100. Because the temperature coefficients with respect to frequency for the first and second mechanical resonators 110, 120 are substantially the same, the difference in frequency between signals from the first mechanical resonator and second mechanical resonator remains constant as the temperature changes.

The temperature coefficient of the difference frequency between signals from the first and second mechanical resonators 110, 120 has a lower temperature coefficient with respect to frequency than the first and second mechanical resonators 110, 120 if the difference between the temperature coefficients with respect to frequency for the first and the second mechanical resonators 110, 120 is less than the temperature coefficient with respect to frequency for both the first and the second mechanical resonators 110, 120.

If the difference between the temperature coefficients with respect to frequency is much less than the temperature coefficient with respect to frequency of both the first and the second mechanical resonators 110, 120 then the frequency output from the frequency generator 100 has a much lower temperature coefficient than the first and the second mechanical resonators 110, 120, assuming that the first and second mechanical resonators 110, 120 are at substantially the same temperature. If the temperature coefficients with respect to frequency of the first and second mechanical resonators 110, 120 are substantially the same, the temperature coefficient of the frequency generator 100 is substantially zero.

In some embodiments, the first and second mechanical resonators 110, 120 are placed close together and, in some other embodiments, in the same environment to ensure that the temperatures of the first and second mechanical resonators are substantially the same at a given time.

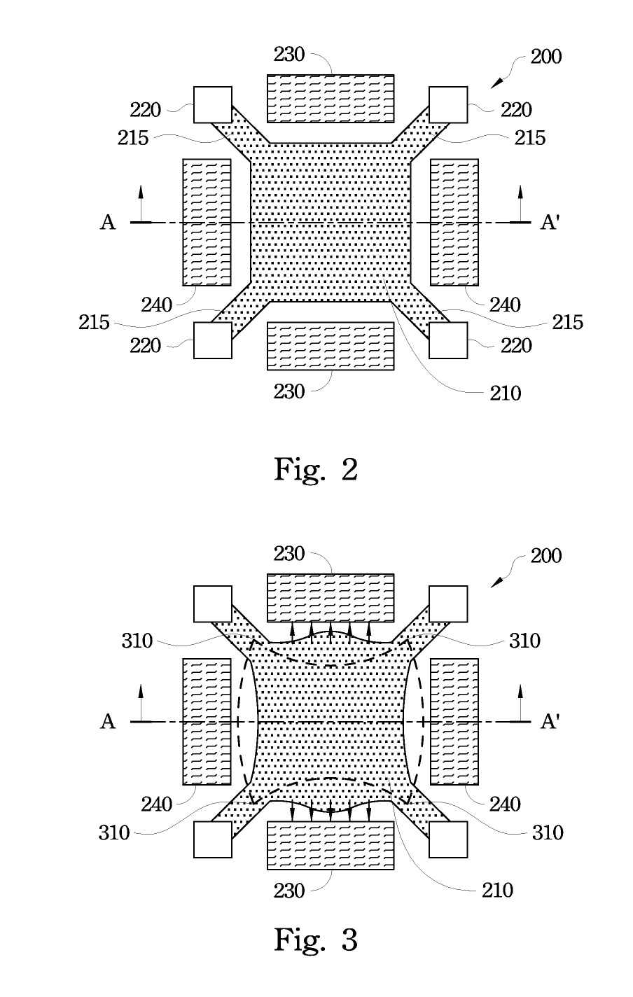

FIG. 2 is a top view of a mechanical resonator 200 according to an embodiment. Resonator 200 comprises a suspended plate 210, suspended by connections 215 between tether points 220. Electrodes 230 and 240 are positioned around the suspended plate 210.

In operation, electrodes 230 excite suspended plate 210 into resonance using electrostatic force generated by a voltage provided between the electrodes 230 and the suspended plate 210. The corresponding driver circuit 130 or 140 (FIG. 1) supplies the voltage to electrodes 230. Electrodes 240 sense the motion of the suspended plate electrostatically. The corresponding driver circuit 130 or 140 senses the motion of the suspended plate 210 using a position, velocity or acceleration signal detected on electrodes 240. Responsive to the position signal, the corresponding driver circuit 130 or 140 adjusts the driver voltage applied to electrodes 230 to keep the resonator resonating at constant amplitude. The first and second drivers 130, 140 comprise, for example, a transimpedance amplifier that amplifies a current generated by the electrodes 240 as the suspended plate 210 moves toward and away from the electrodes 240. The transimpedance amplifier generates a voltage to drive electrodes 230 corresponding to the amplified current. The transimpedance amplifier is configured to generate positive feedback forcing the transimpedance amplifier and the respective resonator into oscillation.

FIG. 3 is a top view of an oscillation mode of the suspended plate 210 (FIG. 2). The shape of the suspended plate 210 in FIG. 3 has the plate pulled toward electrodes 230. If the voltage on electrodes 230 is switched off the suspended plate 210 springs away from the electrodes 230 and expands toward electrodes 240 as indicated by the dotted line 300, then oscillates back to a state in which the plate expands toward electrodes 230 and away from electrodes 240 once again. With correct timing of application of the voltage applied to electrodes 230, the oscillation is maintained. The oscillation mode of the suspended plate 210 has nodes 310 that are substantially stationary when the suspended plate is oscillating in the mode of FIG. 3.

The oscillation mode of the suspended plate 210 in FIG. 3 represents the lowest resonant mode of the suspended plate 210. In other embodiments, other resonant modes of the suspended plate are used to generate the reference signals using the drivers 110, 120. The oscillation mode of FIG. 3 is in the plane of the suspended plate 210. In other embodiments, oscillation modes of the suspended plate 210 that move portions of the suspended plate out of the plane of the stationary suspended plate are used.

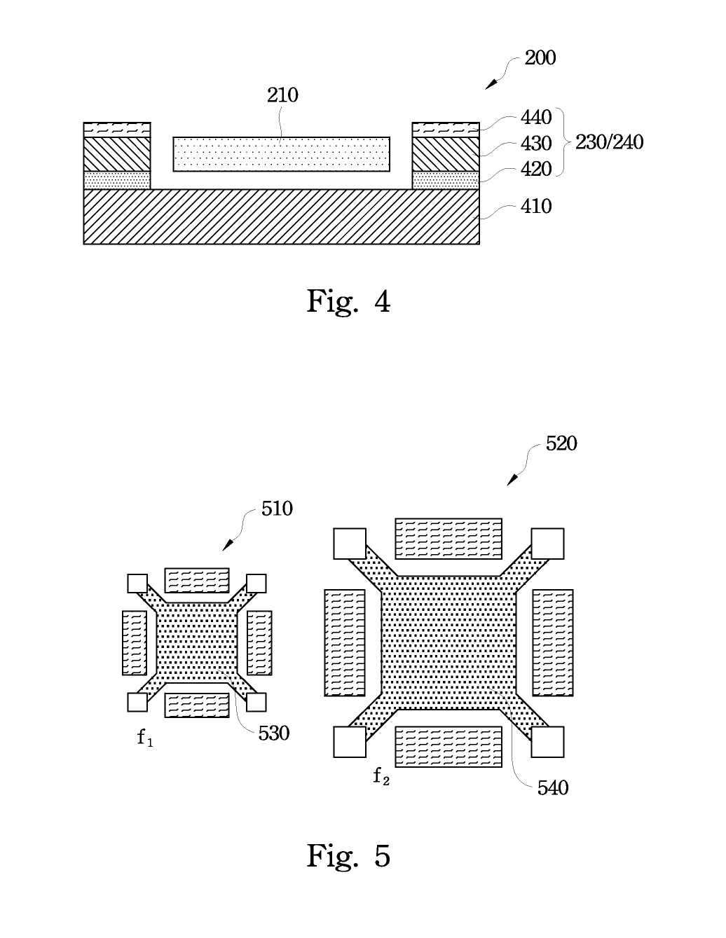

FIG. 4 is a cross-section through FIG. 2 along the line A-A′. The mechanical resonator is formed on a substrate 410. The substrate 410 is formed of an elementary semiconductor, such as silicon, diamond or germanium; a compound semiconductor, such as silicon carbide, indium arsenide or indium phosphide; or an alloy semiconductor, such as silicon germanium carbide, gallium arsenide phosphide, or gallium indium phosphide. Alternatively, the substrate 110 may include a non-semiconductor material such as a glass for thin-film-transistor liquid crystal display (TFT-LCD) devices, fused quartz or Aluminum Titanium Carbide.

An insulating layer 420 formed from, for example, silicon dioxide, silicon nitride, alumina or low dielectric-constant (low-k) material is formed on the substrate. A conductor layer 430 formed on insulating layer 420 is used to form electrodes 230 and 240 and suspended plate 210.

Conductor layer 430 is formed from, for example, silicon, polysilicon, silicon germanium metal films or a combination thereof. Metal contacts 440 formed on top of the conductor layer 430 position of electrodes 230 and 240 allow for connection to the electrodes by, for example, wire bonding, die bonding or wiring used to form connections on a semiconductor device. The metal contacts 440 are formed from, for example, copper, gold, nickel, chromium, aluminum, titanium, titanium nitride, tantalum, alloys of the foregoing metals or combinations of layers of the foregoing materials. Suspended plate 210 is separated from the substrate 410 and is free to resonate. The tether points 220 are formed from the same insulating layer 420, conductor layer 430 and contacts 440 as the electrodes 230, 240. The metal contact on the tether points allows the suspended plate 210 to be connected to, for example, ground or another voltage. The connections 215 between the tether points and the suspended plate 210 (not shown in FIG. 4) are formed from conductor layer 430.

FIG. 5 is a top view of mechanical resonators 510, 520 that, in some embodiments, form both the first and second mechanical resonators 110, 120. The mechanical resonators 510, 520 are identical in structure to mechanical resonator 200. The mechanical resonators 510, 520 differ in size so that the resonant frequency of mechanical resonator 510 differs from that of mechanical resonator 520. Because the size of the suspended plates 530 and 540 differ, the effective mass and spring constant of the suspended plates differ. A larger size for suspended plate 540 produces a lower resonant frequency compared with the smaller size for suspended plate 530. Further, the oscillation mode of the suspended plates 530, 540 has nodes at the points 310 (FIG. 3) near where the suspended plate attaches to the tether points 220 (FIG. 2). Because of the position of the nodes, the temperature coefficient with respect to frequency of the resonant frequency of the suspended plates 530, 540 does not change appreciably with the size of the suspended plate. The mechanical resonators 510, 520 are fabricated on the same substrate at the same time with the same materials having substantially the same thickness. Therefore, the temperature coefficients of the resonators 510, 520 and the aging of the resonators is substantially the same and the frequency shift of the resonators with age and temperature is substantially the same.

In other embodiments, the shape of the suspended plates 530, 540 differ. If the shape of the suspended plates 530, 540 is altered the resonant frequency of the plate is changed. Changes in shape of suspended plates 530, 540 include, for example, the shape of the periphery of the suspended plate or holes or slots cut through or defined in the body of the plate.

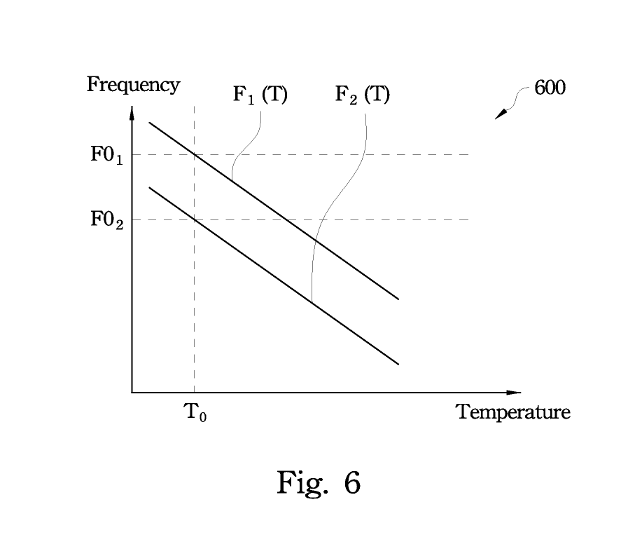

FIG. 6 is a frequency versus temperature plot 600 for the resonators 510, 520 for the embodiment in FIGS. 1, 2 and 5. The plot 600 depicts the change of the resonant frequency for the mechanical resonators 510, 520 with temperature. The first proximation temperature coefficient with respect to frequency is constant, and is represented in equations (1) and (2) below, where F₁(T) and F₂(T) are the resonant frequencies of mechanical resonators 510, 520, F0₁ and F0₂ are the resonant frequencies of mechanical resonators 510, 520 at a temperature T₀ and α is the temperature coefficient with respect to frequency of the mechanical resonators 510, 520. Equation (3)) below, is the result of subtracting equation (1) from equation (2), where F₁₋₂(T) is the difference frequency. The difference frequency is substantially independent of temperature so long as the value of α is equal for both resonators 510, 520. If the value of α is constant, the temperature coefficient with respect to frequency of the mechanical resonators is linear.

F₁(T)=F0₁+αT (1)

F₂(T)=F0₂+αT (2)

F₁₋₂(T)=F₁(T)−F₂(T)=F0₁−F0₂ (3)

In some embodiments, the value of α is not constant with temperature T or humidity H, i.e. α is a function of T and H, α(T,H). As long as α(T,H) is substantially the same for both mechanical resonators 510, 520, and at any given moment H and T are substantially the same for both mechanical resonators, the difference frequency remains substantially independent of temperature and humidity. In some embodiments, the function a includes environmental conditions that are substantially the same for both mechanical resonators placed in the same environment. Such environmental conditions, as well as temperature or humidity, include, for example, gravity, acceleration, light exposure, ionizing and non ionizing radiation exposure, age of the resonator and surrounding components, vibration and sound exposure. As noted above, to ensure that the mechanical resonators 510, 520 are in the same environment and, therefore, have the same value for a, in some embodiments, the mechanical resonators are placed close to each other sharing the same environment. Further, in some embodiments, the mechanical resonators 510, 520 are sealed in the same environment by, for example, a hermetic seal. Such a hermetic seal 126 (FIG. 1), helps to keep the mechanical resonators at the same temperature and humidity as well as protecting the mechanical resonators from the external environment.

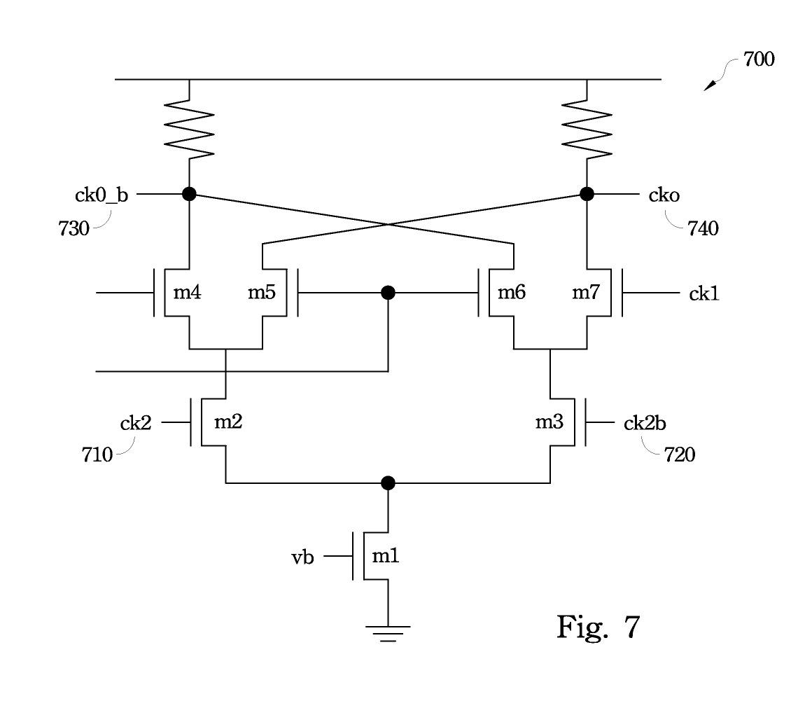

FIG. 7 is a schematic diagram of a mixer circuit 700 usable as a mixer 150 (FIG. 1) according to an embodiment. The mixer circuit 700 has inputs 710, 720 for receiving the output of the driver circuits 130, 140 (FIG. 1). The mixer circuit 700 multiplies signals received at the inputs 710, 720 to produce outputs at 730, 740. The multiplied outputs at 730, 740 include frequency components that are harmonics of the resonant frequencies of the resonators 110, 120 and also the sum of F₁(T) and F₂(T) and the difference F₁₋₂(T) of those two frequency signals. The mixer circuit 700 is a multiplying circuit. In other embodiments, the mixer circuit is a circuit compatible with embodiments of the disclosure that output a component corresponding to the difference between the two frequencies F₁(T) and F₂(T). In some embodiments, the mixer circuit is a non-linear circuit with a single input supplied with the sum of F₁(T) and F₂(T) that outputs, at least, the difference frequency component.

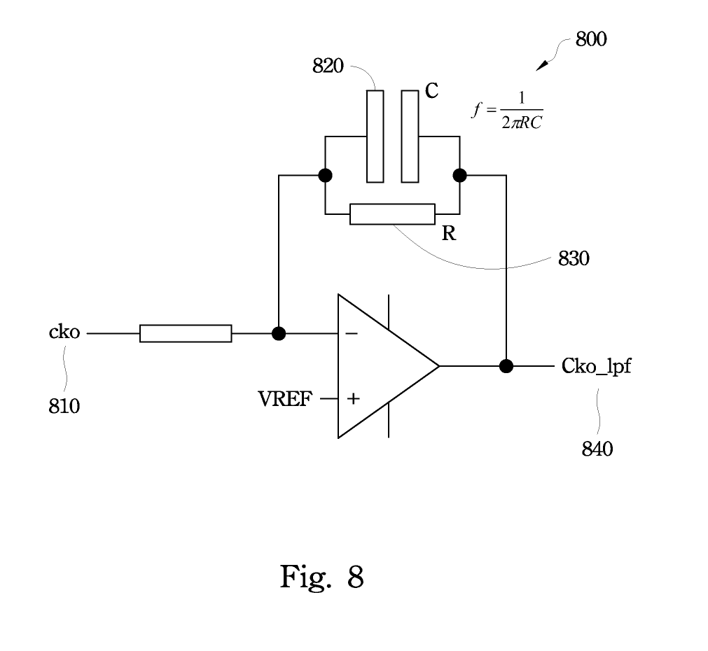

FIG. 8 is a schematic diagram of a filter circuit 800 usable as a filter 160 (FIG. 1) according to an embodiment. At least one output 730 or 740 from mixer 700 (FIG. 7) is supplied to the filter circuit 800 at input 810. The value C of a capacitor 820 and the value R of a resistor 830 are selected such that the filter circuit 800 rejects frequencies above a frequency corresponding to approximately 1/(2πRC). The value of 1/(2πRC) is selected to reject frequencies above the difference F₁₋₂(T). Thus, an output 840 of filter circuit 800 is the difference F₁₋₂(T). In other embodiments, the filter circuit is a circuit compatible with an embodiment of the disclosure which filters all but the difference frequency F₁₋₂(T). For example, a low pass filter circuit of higher order than the filter circuit in FIG. 7 or a band pass filter circuit of any order.

In the embodiments of FIGS. 2-5, the mechanical resonators 110, 120 are MEMS devices. In other embodiments, the MEMS devices include a MEMS resonator compatible with embodiments of the disclosure in which the temperature coefficient with respect to frequency of the resonator is approximately independent of the resonant frequency of the resonator. In other embodiments, the mechanical resonators 110, 120 are resonators compatible with embodiments of the disclosure, for example, quartz crystal resonators, mechanical resonators, piezo electric resonators, balance wheels and pendulums in which the temperature coefficient with respect to frequency of the resonator is approximately independent of the resonant frequency of the resonator.

The embodiment of FIG. 1 includes mechanical resonators 110, 120. In other embodiments, the frequency generator 100 comprises more than two mechanical resonators. If, for example, the frequency generator 100 comprises four mechanical resonators with substantially the same resonant frequency temperature coefficients with respect to frequency then one of several potential difference frequencies between two of the four mechanical resonators is a possible difference frequency. The possible stable reference frequency is output when the reference signals from the drivers of two mechanical resonators are supplied to a mixer circuit 150 and an appropriately adjusted filter circuit 160. With four mechanical resonators, a total of six difference frequencies is selectable as a combination of output frequencies. In general for n mechanical resonators, a combination of

$${\sum }_{m = n - 1}^{m = 1} m$$

or n(n−1)/2 output difference frequencies are selectable.

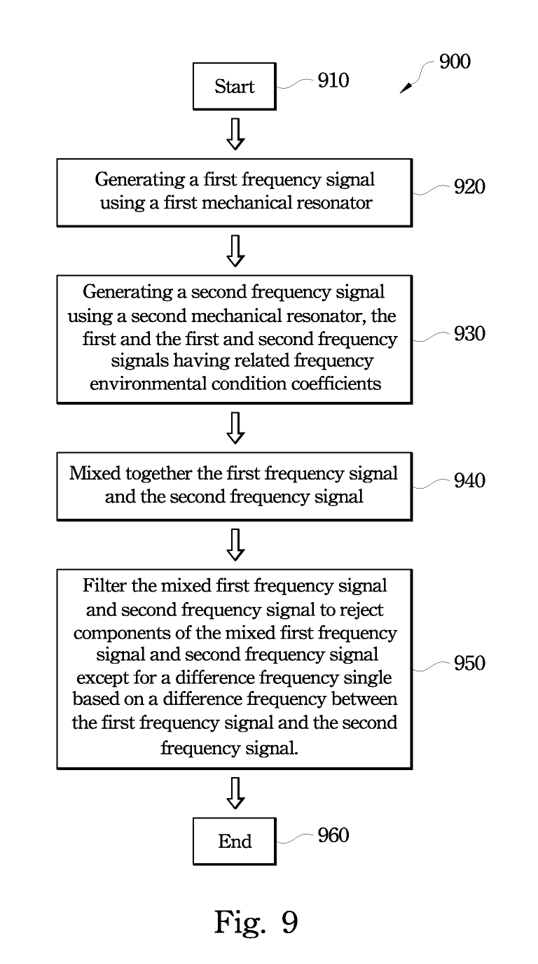

FIG. 9 is a flow diagram 900 of a method of producing a reference frequency using mechanical resonators.

The method begins at step 910 and proceeds to step 920.

At step 920, the first mechanical resonator 110 generates a first frequency signal responsive to the first driver circuit 130. The method proceeds to step 930.

At step 930, the second mechanical resonator generates a second frequency signal responsive to the second driver circuit 140. The first mechanical resonator 110 and the second mechanical resonator 120 are configured to have related frequency environmental condition coefficients. Next, the method proceeds to step 940.

At step 940, the first frequency signal and the second frequency signal are mixed together in a mixing circuit, as described above. The mixing of the first frequency signal and the second frequency signal produces, among other signals, a signal at the difference frequency between the first frequency signal and the second frequency signal. Next, the method proceeds to step 950.

At step 950, the output from the mixer circuit is filtered to derive the difference frequency between the first frequency signal and the second frequency signal. In at least some embodiments, the output from the mixer circuit is filtered to remove all frequencies output by the mixer circuit except the difference frequency. The method proceeds to step 960 where the method terminates.

The above method steps are exemplary and additional method steps may be added or inserted between the above-described steps. Further, any order of the above steps compatible with embodiments of the disclosure is within the scope of the disclosure.

A frequency generator comprising, a first mechanical resonator, a second mechanical resonator and a circuit. The first mechanical resonator with a first predetermined resonant frequency adapted to generate a first mechanical resonator frequency signal based on the first predetermined resonant frequency. The second mechanical resonator with a second predetermined resonant frequency adapted to generate a second mechanical resonator frequency signal based on the second predetermined resonant frequency. The first and second mechanical resonators adapted to have substantially the same frequency coefficients as a function of an environment of the first and the second mechanical resonators, the first mechanical resonator differing in size from the second mechanical resonator. The circuit connected with the first and second mechanical resonators and adapted to generate a difference frequency signal responsive to the first and second mechanical resonator frequency signals and based on the first and the second predetermined resonant frequencies.

A frequency generator system comprising, a first mechanical resonator, a second mechanical resonator, a mixer circuit and a filter circuit. The first mechanical resonator comprising a first suspended resonator plate and a first output. The second mechanical resonator comprising a second suspended resonator plate and a second output. The first and second suspended resonator plates having different sizes. The mixer circuit comprising first and second inputs and a third output. The first input connected to the first output and the second input connected to the second output. The mixer circuit adapted to generate on the third output a difference frequency signal between signals on the first and second inputs. The filter circuit comprising a third input and a fourth output, the third input connected to the third output, the filter circuit adapted to output the difference frequency signal on the fourth output.

A method of generating a frequency signal comprising, generating a first frequency signal, generating a second frequency signal and generating a difference frequency signal. The first frequency signal generated using a first mechanical resonator with a first predetermined resonant frequency. The second frequency signal generated using a second mechanical resonator with a second predetermined resonant frequency. The first and the second mechanical resonators having substantially the same frequency coefficients as a function of an environment of the first and the second mechanical resonator. The second mechanical resonator being a different size from the first mechanical resonator. The difference frequency signal generated responsive to the first and second frequency signals and based on a difference frequency between the first predetermined resonant frequency and the second predetermined resonant frequency.

It will be readily seen by one of ordinary skill in the art that the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed:

1. A frequency generator comprising:
a first mechanical resonator with a first predetermined resonant frequency adapted to generate a first mechanical resonator frequency signal based on the first predetermined resonant frequency;
a second mechanical resonator with a second predetermined resonant frequency adapted to generate a second mechanical resonator frequency signal based on the second predetermined resonant frequency, the first and the second mechanical resonators adapted to have substantially the same frequency coefficients as a function of an environment of the first and the second mechanical resonators, the first mechanical resonator differing in size from the second mechanical resonator; and
a circuit connected with the first and second mechanical resonators and adapted to generate a difference frequency signal responsive to the first and second mechanical resonator frequency signals and based on the first and the second predetermined resonant frequencies.

2. The frequency generator according to claim 1, the first mechanical resonator further comprising a first suspended resonator plate and the second mechanical resonator further comprising a second suspended resonator plate the first suspended resonator plate differing in size from the second suspended resonator plate.

3. The frequency generator according to claim 1, the first mechanical resonator further comprising a first suspended resonator plate and the second mechanical resonator further comprising a second suspended resonator plate the first suspended resonator plate differing in shape from the second suspended resonator plate.

4. The frequency generator according to claim 3, the first suspended resonator plate formed from the same material as the second suspended resonator plate.

5. The frequency generator according to claim 4, the first suspended resonator plate formed from at least one of silicon or polysilicon.

6. The frequency generator according to claim 1, the frequency coefficients of the first and the second mechanical resonators having substantially the same frequency coefficient function with at least one of temperature, acceleration, humidity, gravity, radiation, light or age.

7. The frequency generator according to claim 1, the circuit further comprising a mixer circuit adapted to generate a mix of the first and the second mechanical resonator frequency signals responsive to the first and the second predetermined resonant frequencies.

8. The frequency generator according to claim 7, the mixer circuit being a multiplying circuit that multiplies the first mechanical resonator frequency signal with the second mechanical resonator frequency signal.

9. The frequency generator according to claim 8, further comprising a filter circuit adapted to filter an output of the mixer circuit based on the first and the second predetermined resonant frequencies and generate an output that includes the difference frequency signal.

10. The frequency generator according to claim 1, the first and the second mechanical resonators placed in the same environment.

11. A frequency generator system comprising:
a first mechanical resonator comprising a first suspended resonator plate and a first output;
a second mechanical resonator comprising a second suspended resonator plate and a second output, the first and second suspended resonator plates having different sizes;
a mixer circuit comprising first and second inputs and a third output, the first input connected to the first output and the second input connected to the second output, the mixer circuit adapted to generate on the third output a difference frequency signal between signals on the first and second inputs;
a filter circuit comprising a third input and a fourth output, the third input connected to the third output, the filter circuit adapted to output the difference frequency signal on the fourth output.

12. The frequency generator system according to claim 11, the first and second suspended resonator plates formed from the same material.

13. The frequency generator system according to claim 11, the resonator frequency coefficients of the first and the second mechanical resonators adapted to have substantially the same frequency coefficient function with respect to at least one of temperature, humidity, acceleration, gravity, radiation, light or age.

14. The frequency generator system according to claim 11, the first and second mechanical resonators placed in the same environment.

15. The frequency generator system according to claim 14, the first and second mechanical resonators hermetically sealed in the same environment.

16. A method of generating an frequency signal comprising:
generating a first frequency signal using a first mechanical resonator with a first predetermined resonant frequency;
generating a second frequency signal using a second mechanical resonator with a second predetermined resonant frequency, the first and the second mechanical resonators having substantially the same frequency coefficients as a function of an environment of the first and the second mechanical resonator, the second mechanical resonator being a different size from the first mechanical resonator; and
generating a difference frequency signal responsive to the first and second frequency signals and based on a difference frequency between the first predetermined resonant frequency and the second predetermined resonant frequency.

17. The method according to claim 16, a suspended resonator plate of the first mechanical resonator formed from the same material as a suspended resonator plate of the second mechanical resonator.

18. The method according to claim 16, the frequency coefficients of the first and the second mechanical resonators having substantially the same frequency coefficient function with at least one of temperature, humidity acceleration, gravity, radiation, light or age.

19. The method according to claim 16, the generating the difference frequency signal further comprising mixing the first frequency signal and the second frequency signal.

20. The method according to claim 19, further comprising filtering the mixed the first frequency signal and the second frequency signal based on the first and the second predetermined resonant frequencies to allow through the difference frequency signal.
